(19) United States
(12) Patent Application Publication
(10) Pub. No.: US 2021/0301871 A1
(43) Pub. Date: Sep. 30, 2021

(54) POSITIONING DEVICES FOR RADIALLY POSITIONING SUBSTRATES WITH RESPECT TO AN AIR BEARING DEVICE

(71) Applicant: CORNING INCORPORATED, CORNING, NY (US)

(72) Inventors: Ronnie Rex Fesperman, JR., Statesville, NC (US); Jesse Michael Groover, Corning, NY (US)

(21) Appl. No.: 17/206,982

(22) Filed: Mar. 19, 2021

Related U.S. Application Data
(60) Provisional application No. 63/000,852, filed on Mar. 27, 2020.

(51) Int. Cl. F16C 32/06; H01L 21/687

(52) U.S. Cl. CPC F16C 32/0648; F16C 32/0603; H01L 21/68735

(57) ABSTRACT

A substrate positioning device for radially positioning a substrate including a first mounting frame, and a plurality of centering devices coupled to the first mounting frame and spaced apart from one another. Each of the plurality of centering devices including a mount, a flexure element coupled to the mount and having a radial edge, and an adjustment member coupled to the mount. The adjustment member is adjusting between a retracted state and an extended state for pivoting the flexure element between a first position and a second position with respect to the mount. Each centering device is separately actuatable to move the flexure element of a respective centering device with respect to an edge of the substrate thereby radially positioning the substrate with respect to the first mounting frame.

### CROSS-REFERENCE TO RELATED APPLICATIONS

This application claims the benefit of priority under 35 U.S.C. § 119 of U.S. Provisional Application Ser. No. 63/000,852 filed on Mar. 27, 2020, the content of which is relied upon and incorporated herein by reference in its entirety.

### TECHNICAL FIELD

The present specification generally relates to apparatuses and methods for positioning substrates and, more specifically, to apparatuses and methods for radially positioning substrates and reducing physical contact with the substrates.

### BACKGROUND

In different industries, substrates, such as glass or silicon wafers used in semiconductor processing, are utilized and, in doing so, subjected to handling, chucking, centering, and inspection. For example, in some instances, substrates may be positioned on an end effector of a robot to be transported. In other instances, a substrate may be positioned within an interferometer, such as a Fizeau interferometer, for measuring one or both surfaces of the substrate.

Specifically, thin, large-diameter substrates are extremely sensitive to external influences, such as floor vibrations, airflow, acoustics, temperature, and humidity. Thus, in positioning the substrate with respect to either an end effector of a robot or an interferometer, contact with the substrate itself can result in inaccurate measurement readings or even damage to the substrate itself.

Accordingly, a need exists for alternative substrate positioning devices for substrates that reduce contact with the substrate.

### SUMMARY

According to a first aspect disclosed herein, a substrate positioning device comprises a first mounting frame; and a plurality of centering devices coupled to the first mounting frame and spaced apart from one another, each centering device comprising a mount, a flexure element coupled to the mount and having a radial edge, and an adjustment member coupled to the mount, the adjustment member actuatable between a retracted state and an extended state for pivoting the flexure element between a first position and a second position with respect to the mount, wherein each centering device is separately actuatable to move the flexure element of a respective centering device with respect to an edge of a substrate thereby radially positioning the substrate with respect to the first mounting frame.

According to a second aspect disclosed herein, a substrate positioning device includes the substrate positioning device according to the first aspect, and further comprises a first support including at least one first gas inlet, the first mounting frame being coupled to the first support.

According to a third aspect disclosed herein, a substrate positioning device includes the substrate positioning device according to the first or second aspects, wherein the plurality of centering devices are positioned between the first support and a second support including at least one second gas inlet.

According to a fourth aspect disclosed herein, a substrate positioning device includes the substrate positioning device according to any of the first through third aspects, wherein the plurality of centering devices are equidistantly spaced apart from one another along the first mounting frame.

According to a fifth aspect disclosed herein, a substrate positioning device includes the substrate positioning device according to any of the first through fourth aspects, wherein the flexure element includes a drive arm; a preload arm; a fixed arm; a leg interconnecting the drive arm and the preload arm; and a leaf hinge interconnecting the preload arm and the fixed arm, wherein the drive arm, the preload arm, and the leg pivot with respect to the mount about the leaf hinge when the adjustment member moves between the retracted state and the extended state and the flexure element moves between the first position and the second position, respectively.

According to a sixth aspect disclosed herein, a substrate positioning device includes the substrate positioning device according to any of the first through fifth aspects, wherein each centering device comprises a biasing member biasing the preload arm, wherein: the biasing member moves toward an expanded state and biases the drive arm toward the mount when the adjustment member moves toward the retracted state; the preload arm causes the biasing member to move toward a compressed state when the adjustment member moves toward the extended state.

According to a seventh aspect disclosed herein, a substrate positioning device includes the substrate positioning device according to any of the first through sixth aspects, wherein the adjustment member extends through the mount and is coupled to the drive arm such that the flexure element is moved toward the second position and away from the mount when the adjustment member moves toward the extended state, and the flexure element is moved toward the first position and toward the mount when the adjustment member moves toward the retracted state.

According to an eighth aspect disclosed herein, a substrate positioning device includes the substrate positioning device according to any of the first through seventh aspects, wherein the adjustment member is an adjustment screw.

According to a ninth aspect disclosed herein, a substrate positioning device includes the substrate positioning device according to any of the first through eighth aspects, and further comprises an adjustment sensor for measuring movement of the adjustment member between the retracted state and the extended state.

According to a tenth aspect disclosed herein, a substrate positioning device includes the substrate positioning device according to any of the first through ninth aspects, and further comprises a tab provided on a radial edge of the flexure element for contacting the edge of the substrate.

According to an eleventh aspect disclosed herein, a substrate positioning device comprises a first mounting frame; and a plurality of centering devices coupled to the first mounting frame and spaced apart from one another, each centering device including a mount, a flexure element, and an adjustment member actuatable between a retracted state and an extended state for pivoting the flexure element between a first position and a second position with respect to the mount, and a radial air bearing extending from the flexure element, wherein: the radial air bearing forms an air cushion between the radial air bearing and an edge of a substrate; and each centering device is separately actuatable to move the flexure element of a respective centering device with respect to the edge of the substrate thereby radially positioning the substrate with respect to the first mounting frame.

According to a twelfth aspect disclosed herein, a substrate positioning device includes the substrate positioning device according to the eleventh aspect, and further comprises a first support including at least one first gas inlet, the first mounting frame being coupled to the first support.

According to a thirteenth aspect disclosed herein, a substrate positioning device includes the substrate positioning device according to the eleventh or twelfth aspects, wherein the plurality of centering devices are equidistantly spaced apart from one another along the first mounting frame.

According to a fourteenth aspect disclosed herein, a substrate positioning device includes the substrate positioning device according to any one of the eleventh through thirteenth aspects, wherein each radial air bearing includes a radial cavity, each radial air bearing including a first flow channel delivering a flow of air to the radial cavity.

According to a fifteenth aspect disclosed herein, a substrate positioning device includes the substrate positioning device according to any one of the eleventh through fourteenth aspects, wherein each radial air bearing includes a radial cavity, each radial air bearing including a first flow channel delivering a flow of air to the radial cavity.

According to a sixteenth aspect disclosed herein, an interferometer includes the substrate positioning device of any of the eleventh through fifteenth aspects.

According to a seventeenth aspect disclosed herein, a method for radially positioning a substrate comprises positioning a substrate with respect to a first mounting frame; coupling a plurality of centering devices to the first mounting frame, each centering device including a mount, a flexure element having a radial edge and positionable between a first position and a second position, and an adjustment member actuatable between a retracted state and an extended state for pivoting the flexure element with respect to the mount; and actuating at least one of the centering devices to move the flexure element from the first position to the second position and toward an edge of the substrate to radially position the substrate with respect to the first mounting frame.

According to an eighteenth aspect disclosed herein, a method for radially positioning a substrate according to the seventeenth aspect, further comprises positioning the substrate between the first mounting frame and a second mounting frame, the flexure element of each of the plurality of centering devices positioned between the first mounting frame and the second mounting frame.

According to a nineteenth aspect disclosed herein, a method for radially positioning a substrate according to the seventeenth or eighteenth aspects, wherein each centering device includes an adjustment sensor, the adjustment sensors measuring a distance of a respective flexure element between the first position and the second position and corresponding this distance to a radial position of the substrate.

According to a twentieth aspect disclosed herein, a method for radially positioning a substrate according to any one of the seventeenth through nineteenth aspects, wherein each of the centering devices includes a radial air bearing for radially positioning the substrate with respect to the first mounting frame, and forming an air cushion between each of the radial air bearings and the edge of the substrate.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of an example substrate positioning device including a plurality of centering devices positioned on a mounting frame, according to one or more embodiments shown and described herein;

FIG. 2 schematically depicts a perspective view of a centering device of the substrate positioning device of FIG. 1 in a first position, according to one or more embodiments shown and described herein;

FIG. 3 schematically depicts a perspective view of the centering device of FIG. 2 in a second position, according to one or more embodiments shown and described herein;

FIG. 4 schematically depicts a cross-sectional view of the centering device of FIG. 2 positioned between the first mounting frame, a second mounting frame, and a pair of air bearings, according to one or more embodiments shown and described herein;

FIG. 5 schematically depicts a perspective view of an example substrate positioning device including a plurality of centering devices positioned on a mounting frame, according to one or more embodiments shown and described herein;

FIG. 6 schematically depicts a perspective view of a centering device of the substrate positioning device shown in FIG. 5 in a first position, according to one or more embodiments shown and described herein;

FIG. 7 schematically depicts a cross-sectional view of an example radial air bearing of the centering device of FIGS. 5 and 6, according to one or more embodiments shown and described herein;

FIG. 8 schematically depicts a cross-sectional view of an example radial air bearing of the centering device of FIGS. 5 and 6, according to one or more embodiments shown and described herein;

FIG. 9 schematically depicts a cross-sectional view of an example radial air bearing of the centering device of FIGS. 5 and 6, according to one or more embodiments shown and described herein; and

FIG. 10 schematically depicts an interferometer including an example substrate positioning device.

### DETAILED DESCRIPTION

Embodiments described herein are directed to substrate positioning devices that include centering devices arranged around a substrate for radially positioning the substrate with respect to the substrate positioning device.

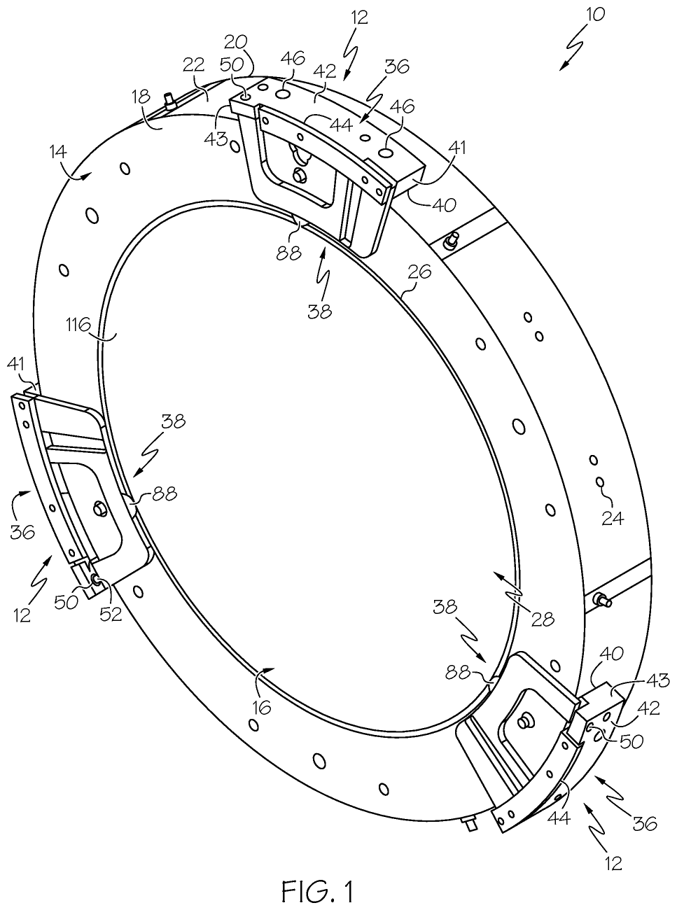

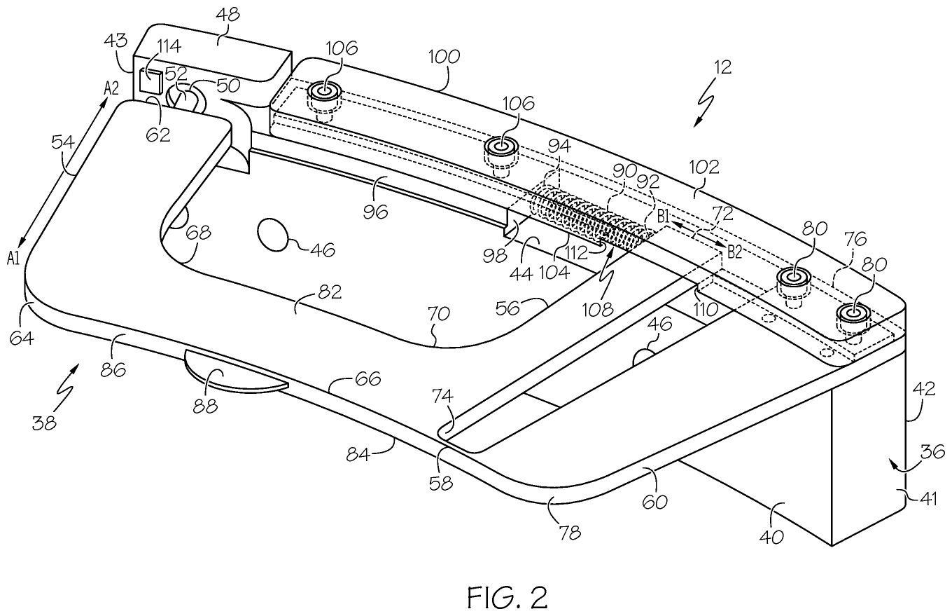

An embodiment of the substrate positioning device with a plurality of centering devices is depicted in FIG. 1 and an embodiment of a centering device is depicted in FIG. 2. As shown in FIG. 2, the centering device includes a mount 36, a flexure element 38 having a radial edge 86, and an adjustment member 52 for pivoting the flexure element 38 with respect to the mount 36. The centering device is positionable from a first position and a second position such that actuation from the first position to the second position radially moves the flexure element toward an edge of a substrate held by the substrate positioning device. A plurality of centering devices arranged around the substrate may be separately actuated to radially position the substrate. This allows for the substrate to be positioned with minimal contact to the substrate itself, thereby reducing the possibility of contamination, damage, and interference. Various embodiments of substrate positioning devices and the operation of the substrate positioning devices are described in more detail herein with specific reference to the appended drawings. Whenever possible, the same reference numerals will be used throughout the drawings to refer to the same or like parts.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply ab solute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

Referring now to FIG. 1, a substrate positioning device 10 is illustrated according to one or more embodiments described herein. The substrate positioning device 10 disclosed herein generally comprises a plurality of centering devices 12 mounted to a mounting frame 14 for radially positioning a substrate 16, such as a silicon wafer, a glass wafer, or the like.

It is appreciated that the substrate positioning device 10 is suitable for positioning substrates and other objects having varying shapes and sizes. The substrate 16 illustrated herein has a circular geometry. Accordingly, the mounting frame 14 also has a circular geometry corresponding to the substrate 16. However, it should be understood that the substrate 16 may have different geometries and that the mounting frame 14 may have a corresponding geometry for receiving the substrate 16. As such, it is not meant for reference to the shape and size of the substrate 16 to be limiting.

In the embodiment depicted in FIG. 1, the mounting frame 14 has a circular geometry to conform to the shape of the substrate 16. Specifically, the mounting frame 14 has a first surface 18, a second surface 20, and an edge surface 22 interconnecting the first surface 18 and the second surface 20. The edge surface 22 has a curved contour to conform to the shape of the centering devices 12. However, any other contour is contemplated based on the configuration of the centering devices 12. The edge surface 22 of the mounting frame 14 also has a plurality of mounting apertures 24 for mounting the centering devices 12 thereto, as discussed in more detail herein. The mounting frame 14 has a lip 26 defining an opening 28 for receiving the substrate 16.

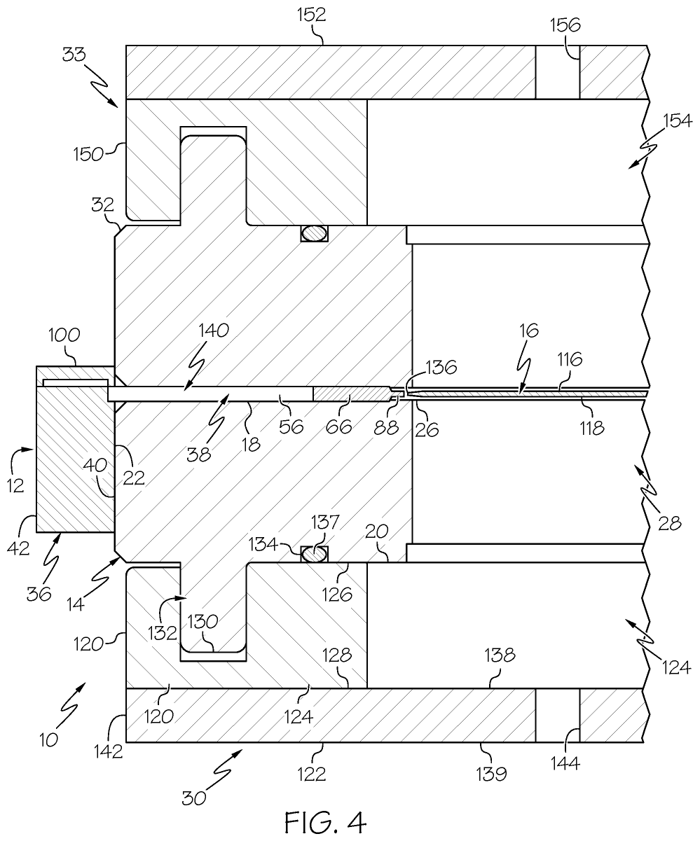

As discussed in more detail below, and illustrated in FIG. 4, the mounting frame 14 facilitates attaching the substrate positioning device 10 to an air bearing device or a first support 30 such as, for example, an air bearing device of a substrate handling device or an interferometer and, more particularly, a Fizeau interferometer, for measuring a surface of the substrate 16. In addition, as discussed herein, the substrate positioning device 10 may include a second mounting frame 32 on an opposite side of the substrate positioning device 10 for attaching the substrate positioning device 10 to a second air bearing device or a second support 33 for simultaneously measuring opposite surfaces of the substrate 16.

Still referring to FIG. 1, the substrate positioning device, comprises three centering devices 12. In some embodiments, the centering devices 12 are equidistantly spaced apart from one another along the edge surface 22 of the mounting frame 14. Thus, in this embodiment, the centering devices 12 are spaced apart from one another by 120-degree increments. However, it should be understood that other arrangements and spacings for the centering devices 12 are contemplated and possible. For example, in embodiments, more or fewer centering devices 12 may be employed. Further, in embodiments, the centering devices may not be equidistantly spaced along the edge surface 22 of the mounting frame 14.

The centering devices 12 are mounted to the edge surface 22 of the mounting frame 14 using any suitable means, such as rivets, screws, clamps, welding, adhesive, and the like. In some embodiments, the centering devices 12 are mounted to the edge surface 22 of the mounting frame 14 using screws inserted through the centering devices 12 and into the mounting apertures 24 of the mounting frame 14.

Each centering device 12 is substantially similar in structure and operation and, thus, only one centering device 12 will be described in detail throughout the ensuing description. Thus, reference to an individual centering device 12 is equally applicable to each of the centering devices 12.

Referring now to FIGS. 1 and 2, a centering device 12 is shown apart from the mounting frame 14. The centering device 12 generally includes a mount 36 and a flexure element 38 coupled to the mount 36. The mount 36 has an interior surface 40, a pair of side surfaces 41, 43, an exterior surface 42, and an end surface 44. In an embodiment, the interior surface 40 of the mount 36 is curved and has at least one centering aperture 46. As shown, a plurality of centering apertures 46 are provided on the mount 36 of the centering device 12 for fixing the centering device 12 to the mounting frame 14. When fixing the centering device 12 to the mounting frame 14, the centering device 12 is positioned along the edge surface 22 of the mounting frame 14. The centering apertures 46 of the centering device 12 are aligned with the mounting apertures 24 of the mounting frame 14 and fixed using mechanical fasteners. In some embodiments, the mount 36 includes an adjustment receiving block 48 provided on the end surface 44 of the mount 36. The adjustment receiving block 48 may be integrally formed with the mount 36 as a one piece monolithic structure formed of the same material or may be fixed thereto using any suitable means, such as mechanical fasteners, adhesives, welding or the like. The adjustment receiving block 48 includes a bore 50 extending therethrough and receives an adjustment member 52 extending through the bore 50 from the exterior surface 42 of the mount 36.

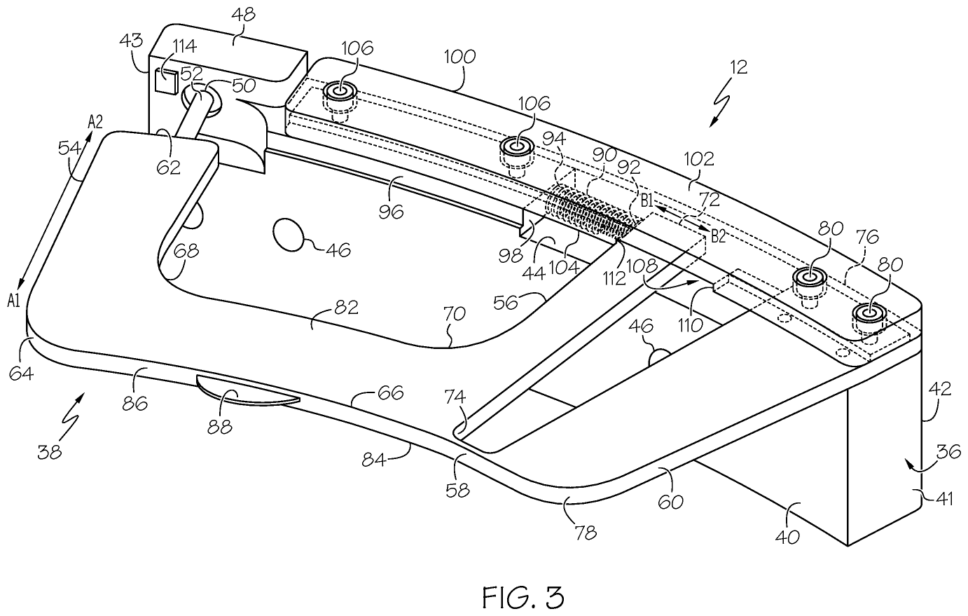

In embodiments, the flexure element 38 of the centering device 12 extends substantially orthogonal to the interior surface 40 of the mount 36 and cantilevered thereto to pivot in a direction A1 and a direction A2 substantially orthogonal to the interior surface 40 of the mount 36, as discussed in more detail herein. The flexure element 38 includes a drive arm 54, a preload arm 56, a leaf hinge 58, and a fixed arm 60. The flexure element 38 includes a leg 66 interconnecting the drive arm 54 and the preload arm 56. The drive arm 54 has a first end 62 and a second end 64. In embodiments, the drive arm 54 is coupled to the mount 36 by the adjustment member 52 at the first end 62 thereof. Alternatively, in embodiments, the first end 62 of the drive arm 54 may abut against the adjustment member 52 and not be fixed thereto. The drive arm 54 extends in the radial direction with respect to the substrate 16 (FIG. 1). As discussed in more detail herein, the adjustment member 52 is operable from a retracted state (FIG. 2) to an extended state (FIG. 3). As the adjustment member 52 moves toward the extended state, the adjustment member 52 pushes the drive arm 54 in the direction A1 away from the interior surface 40 of the mount 36 and the leg 66 pivots about the leaf hinge 58.

The leg 66 of the flexure element 38 has a first end 68 and a second end 70 interconnecting the drive arm 54 at the second end 64 thereof to the preload arm 56. The preload arm 56 has a first end 72 and a second end 74, the second end 74 thereof being fixed to the second end 70 of the leg 66. The first end 72 is positioned and extends adjacent the end surface 44 of the mount 36 and is movable therealong in a direction B1 and a direction B2, as discussed in more detail herein. Thus, the drive arm 54 and the preload arm 56 are fixed to one another by the leg 66 of the flexure element 38. As such, radial movement of the drive arm 54 in the direction A1 and the direction A2 with respect to the adjustment receiving block 48 and the interior surface 40 of the mount 36 causes corresponding movement to the preload arm 56 along the end surface 44 of the mount 36 in the direction B1 and the direction B2, respectively.

The fixed arm 60 has a first end 76 and a second end 78. The first end 76 of the fixed arm 60 is fixed to the end surface 44 of the mount 36 by any suitable means. Specifically, as shown in FIG. 2, the first end 76 of the fixed arm 60 is fixed to the end surface 44 of the mount 36 by a pair of fasteners 80, such as screws, dowel pins, or the like. Thus, movement of the fixed arm 60 with respect to the mount 36 is prevented. The second end 78 of the fixed arm 60 is interconnected to the second end 74 of the preload arm 56 by the leaf hinge 58. The leaf hinge 58 is a relatively thin member and, thus, flexible. As a result, the drive arm 54 and the preload arm 56, which are fixed to one another via the leg 66, are permitted to flex with respect to the fixed arm 60 at the leaf hinge 58 when a position of the drive arm 54 relative to the mount 36 is adjusted by the adjustment member 52.

In some embodiments, flexure element 38 including the drive arm 54, the leg 66, the preload arm 56, the fixed arm 60, and the leaf hinge 58 are integrally formed with one another as a one piece, monolithic structure formed of the same material. Specifically, the flexure element 38 may be a monolithic structure formed from the same material and having a constant thickness throughout. Still referring to FIG. 2, the flexure element 38 has a first surface 82, a second surface 84 opposite the first surface 82, and a radial edge 86 extending between the first surface 82 and the second surface 84. A tab 88 is provided on and extends from the radial edge 86 of the flexure element 38 for contacting the substrate 16, as shown in FIG. 4. The radial edge 86 of the flexure element 38 has a contour similar to that of the interior surface 40 and the exterior surface 42 of the mount 36, which generally corresponds to the geometry of the substrate 16. In some embodiments, the tab 88 is a semi-circular member. However, the tab 88 may have any suitable geometry for contacting an edge of the substrate 16. More particularly, the tab 88 extends from the radial edge 86 of the flexure element 38 proximate the leg 66, as shown in FIG. 2.

The centering device 12 includes a biasing member 90, such as a spring or the like, for biasing the first end 72 of the preload arm 56 toward a first position in the direction B2, as shown in FIG. 2. The biasing member 90 has a first end 92 and a second end 94 extending between the first end 72 of the preload arm 56 and the mount 36. In some embodiments, the mount 36 includes a step 96 having a biasing surface 98 extending substantially orthogonal to the end surface 44 of the mount 36. The step 96 may be integrally formed as a one piece, monolithic structure of the same material with the mount 36 at the end surface 44 thereof or may be fixed thereto using any suitable means. The biasing surface 98 of the step 96 forms an abutment for the biasing member 90 to press against opposite the first end 72 of the preload arm 56. The first end 92 and the second end 94 of the biasing member 90 may be fixed to the first end 72 of the preload arm 56 and the biasing surface 98 of the step 96, respectively. Alternatively, the first end 92 and the second end 94 of the biasing member 90 may be retained in position without being fixed as a constant tension is applied by the biasing member 90 on opposite surfaces. As such, the biasing member 90 provides a constant force against the first end 72 of the preload arm 56 to pivot the drive arm 54 in the direction A2 toward the adjustment receiving block 48 when the adjustment member 52 moves toward the retracted state.

In some embodiments, the centering device 12 includes a cover 100 positioned over the end surface 44 of the mount 36 between the interior surface 40 and the exterior surface 42 thereof. As shown in FIGS. 2 and 3, the cover 100 has a first surface 102 and a second surface 104, each having a curved contour to conform to the contour of the end surface 44 of the mount 36. In positioning the cover 100 on the centering device 12, the cover 100 is placed over the first end 72 of the preload arm 56, the first end 76 of the fixed arm 60, and the step 96. The cover 100 is fixed to the mount 36 by any suitable means, such as screws, rivets, clamps, welding, adhesives, and the like. As shown, the fasteners 80 used to secure the first end 76 of the fixed arm 60 to the end surface 44 of the mount 36 are also used to secure the cover 100 to the end surface 44 of the mount 36. In addition, a pair of fasteners 106 may be provided to secure the cover 100 to the step 96. In some embodiments, the cover 100 includes a recess 108 formed in the first surface 102 thereof allowing for the preload arm 56, specifically the first end 72 thereof, to move between the first position and the second position (FIG. 3) between a first stop 110 and a second stop 112. When in the first position, as shown in FIG. 2, the first end 72 of the preload arm 56 abuts against the first stop 110.

As noted above, the centering device 12 includes an adjustment member 52 extending through the bore 50 of the adjustment receiving block 48 for adjusting the position of the flexure element 38. In the first position, as shown in FIG. 2, the adjustment member 52 is in a fully retracted state. Thus, each of the drive arm 54 and the tab 88 is radially retracted toward the mount 36 in the direction A2. In addition, when in the first position, the biasing member 90 is in an expanded state and pushes the first end 72 of the preload arm 56 in the direction B1 toward the first stop 110 of the recess 108 in the cover 100.

It should be appreciated that the adjustment member 52 may be any suitable device for extending the drive arm 54 forward in the direction A1 (i.e., the extended state) and retracting the drive arm 54 to return to its initial position (i.e., the retracted state) in the direction A2. In some embodiments, the adjustment member 52 is a threaded rod or fastener. More particularly, the adjustment member 52 may be a fine thread adjustment screw to allow the adjustment member 52 to be manually adjusted by rotating an accessible end of the adjustment screw from the exterior surface 42 of the mount 36. In other embodiments, the adjustment member 52 may be an actuator such as, for example, a piezo actuator, a voice coil actuator, pneumatic actuator, or any other suitable linear actuator for extending and retracting within the bore 50 of the adjustment receiving block 48 to control movement of the flexure element 38.

When the adjustment member 52 is an actuator, the adjustment member 52 may be automatically operated based on a number of different measurement devices. In some embodiments, an adjustment sensor 114 is provided proximate the adjustment member 52 for measuring operation of the adjustment member 52. The adjustment sensor 114 may be provided between the adjustment receiving block 48 and the first end 62 of the drive arm 54 on either the adjustment receiving block 48 or the drive arm 54 for measuring distance therebetween. In another embodiment, the adjustment sensor 114 may be provided on the adjustment receiving block 48 opposite the first end 62 of the drive arm 54 for measuring extension and retraction of the adjustment member 52 through the bore 50 of the adjustment receiving block 48. The adjustment sensor 114 may be any suitable sensor for measuring distance such as, for example, a linear variable displacement transducer (LVDT), a capacitance displacement sensor, a laser displacement sensor, an eddy current sensor, a confocal sensor, a magneto-inductive distance sensor, or the like. Alternatively, in some embodiments, the adjustment member 52 may include an internal adjustment sensor, such as those identified above, to eliminate the need for an adjustment sensor provided externally of the adjustment member 52 on the adjustment block 48 or the drive arm 54.

Referring now to FIG. 3, the flexure element 38 is illustrated in the second position. In operating the flexure element 38 into or toward the second position from the first position shown in FIG. 2, the adjustment member 52 moves toward the extended state and pushes the first end 62 of the drive arm 54 in the direction A1 and away from the interior surface 40 of the mount 36. In doing so, the drive arm 54 and the preload arm 56 pivot at the leaf hinge 58 with respect to the fixed arm 60 and the mount 36. When the centering device 12 moves toward the second position, the first end 72 of the preload arm 56 moves in the direction B1 toward the biasing surface 98 of the step 96, thereby compressing the biasing member 90 into a compressed state. Once the flexure element 38 is in the second position, the first end 72 of the preload arm 56 contacts the second stop 112, which prevents over pivoting of the preload arm 56 and the flexure element 38. Thus, it should be appreciated that, when in the first position, the tab 88, which is fixed to the flexure element 38, is moved in the direction A2 and brought closer to the mount 36. To the contrary, when in the second position, the tab 88 is moved in the direction A1 and moved further from the mount 36.

Referring now to FIG. 4, a partial cross-sectional view of the substrate positioning device 10 is shown with the interior surface 40 of the mount 36 of the centering device 12 mounted to the edge surface 22 of the mounting frame 14. As discussed herein, the substrate positioning device 10 may be suitable for use in measuring a first surface 116 and an opposite second surface 118 of the substrate 16 as well as handling the substrate 16 during transport. For example, the substrate positioning device 10 may be provided on an end effector (not shown) of a robot arm for use in substrate transport between production equipment. As such, the substrate positioning device 10 may include a single mounting frame 14 for attaching a single air bearing device or support provided on an end effector of a robot arm. The air bearing device forms an air cushion to retain the substrate 16 in an axial position while the centering devices 12 operate to radially position the substrate 16. To release the substrate 16 from the substrate positioning device 10, the air bearing device is deactivated. In some embodiments, the air bearing device may be part of an interferometer and, specifically, a Fizeau interferometer.

As used herein, the term “axial” or an “axial direction” is to be understood as referring to a direction extending substantially perpendicular to a plane defining the first surface 116 or the second surface 118 of the substrate 16. As such, axial movement of the substrate 16 refers to the substrate 16 moving in a linear direction toward or away from the first support 30 within the substrate positioning device 10. In addition, the term “radial” or a “radial direction” as used herein is to be understood as referring to a direction extending substantially parallel to a plane defining the first surface 116 or the second surface 118 of the substrate 16. As such, radial movement of the substrate 16 refers to the substrate 16 moving in a linear direction toward or away from the centering device 12 and radial movement of the flexure element 38 refers to the flexure element 38 moving toward or away from the mount 36 and the substrate 16.

As shown in FIG. 4, the substrate positioning device 10 includes an air bearing device or a first support 30 facing the second surface 118 of the substrate 16. The first support 30 includes a first bearing land 120 and a first bearing base 122 that are arranged to form a first bearing pocket 124. The first bearing land 120 and the first bearing base 122 may be a one piece, monolithic structure formed of the same material. In some embodiments, the first bearing pocket 124 defines a measurement cavity. The first bearing land 120 is coupled to the mounting frame 14 and includes an inner surface 126 and an outer surface 128. The first bearing land 120 is generally a circular member, but may have any suitable geometry corresponding to the geometry of the mounting frame 14. In some embodiments, the mounting frame 14 includes a flange 130 extending along and substantially orthogonal to the second surface 20 of the mounting frame 14 and substantially parallel to the edge surface 22 of the mounting frame 14. In this embodiment, the first bearing land 120 includes a recess 132 formed in inner surface 126 thereof for receiving the flange 130 of the mounting frame 14. The flange 130 may be coupled to the first bearing land 120 using any suitable means, such as rivets, screws, clamps, welding, adhesive, and the like. The inner surface 126 of the first bearing land 120 abuts against the second surface 20 of the mounting frame 14. Further, in some embodiments, the second surface 20 of the mounting frame 14 includes a groove 134 formed therein and extending along the circumference of the mounting frame 14. A gasket 137 may be provided therein to form an airtight seal between the second surface 20 of the mounting frame 14 and the inner surface 126 of the first bearing land 120.

The first bearing base 122 is generally a circular member, but may have any suitable geometry corresponding to the first bearing land 120. The first bearing base 122 has an inner surface 138, an outer surface 139, and an edge surface 142. In some embodiments, the inner surface 138 of the first bearing base 122 is coupled to the outer surface 128 of the first bearing land 120 proximate the edge surface 142 of the first bearing base 122 using any suitable means such as rivets, screws, clamps, welding, adhesive, and the like. In some embodiments, the first bearing base 122 may be coupled to the first bearing land 120 at the edge surface 142 of the first bearing base 122.

In various embodiments, at least part of the first support 30 may be formed from glass or another optically-transparent material. In some embodiments, the first bearing base 122 may be a glass substrate and the first bearing base 122 can be an optical reference. In some embodiments, the optical reference can include a Fizeau wedge mounted within a bezel or other annular housing.

The first support 30 includes at least one gas inlet in fluid communication with the first bearing pocket 124. In some embodiments, a first gas inlet 144 extends through the first bearing base 122 and into the first bearing pocket 124. However, it is to be appreciated that the first gas inlet 144 may alternatively be arranged to extend through the first bearing land 120 and into the first bearing pocket 124. In some embodiments, a plurality of first gas inlets 144 may be provided in either or both of the first bearing land 120 and the first bearing base 122.

As shown in FIG. 4, the interior surface 40 of the mount 36 is positioned against the edge surface 22 of the mounting frame 14 and is fixed thereto. The flexure element 38 is shown extending in the radial direction with respect to the interior surface 40 of the mount 36 and across the first surface 18 of the mounting frame 14 toward the substrate 16, which is positioned axially with respect to the first support 30. Gas is supplied from a gas supply (not shown) to the first bearing pocket 124 through the first gas inlet 144 to form an air bearing in the first bearing pocket 124. In various embodiments, the first support 30, via the air bearing provided within the first bearing pocket 124, supports the substrate 16 and axially positions the substrate 16 without contact between the substrate 16 and the first support 30. In addition to axially positioning the substrate 16, the flow of pressurized gas through the first bearing pocket 124 pushes particulates away from the substrate 16 and out of the first bearing pocket 124, thereby keeping the substrate 16 free of contaminants.

As shown in FIG. 4 and discussed above, in some embodiments, a second mounting frame 32 may be provided to permit use of a second air bearing device or a second support 33 facing the first surface 116 of the substrate 16. It should be understood that the second mounting frame 32 and the second support 33 may be substantially similar in structure and operation as the mounting frame 14 and the first support 30, respectively. As such, the second support 33 includes a second bearing land 150 and a second bearing base 152 that are arranged to form a second bearing pocket 154, defining a measurement cavity on the opposite side of the substrate 16 than the first bearing pocket 124. The second support 33 also includes at least one gas inlet in fluid communication with the second bearing pocket 154. As shown, a second gas inlet 156 extends through the second bearing base 152 and into the second bearing pocket 154 opposite the first gas inlet 144 of the first support 30. However, it is to be appreciated that the second gas inlet 156 may alternatively or additionally be arranged to extend through the second bearing land 150 and into the second bearing pocket 154. In some embodiments, a plurality of second gas inlets 156 may be provided in either or both of the second bearing land 150 and the second bearing base 152.

In this embodiment, the mounting frame 14 and the second mounting frame 32 are coupled to one another by any suitable means, such as mechanical fasteners (not shown) and provide a gap 140 between the mounting frame 14 and the second mounting frame 32. The flexure element 38 of the centering device 12 is positioned within the gap 140 without restricting radial movement of the flexure element 38 between mounting frame 14 and the second mounting frame 32. In some embodiments, the substrate 16 may have a diameter larger than the inner diameter of the mounting frame 14. As such, the outer edge 136 of the substrate 16 may be received within the gap 140. It should be appreciated that utilizing the second support 33 provides for measurements to be taken of both the first surface 116 and the second surface 118 of the substrate 16.

In embodiments in which both the first support 30 and the second support are provided, the flow of air into the first bearing pocket 124 and the second bearing pocket 154 can be adjusted with respect to one another to adjust the axial position of the substrate 16. As such, the gas flowing through the first gas inlet 144 provides a first pressure force in the first bearing pocket 124 and the gas flowing through the second gas inlet 156 provides a second pressure force in the second bearing pocket 154. The particular values for each of the first pressure force and the second pressure force can vary depending on the specific embodiment and can depend at least on the mass of the substrate 16. In embodiments, each of the first pressure force and the second pressure force are selected to support the substrate 16 between the first support 30 and the second support 33 without contact between the opposite first and second surfaces 116, 118 of the substrate 16 and the first support 30 and the second support 33. In some embodiments, the first pressure force is equal to the second pressure force. In some embodiments, the first pressure force is different from the second pressure force. For example, the first pressure force can be greater than the second pressure force or the first pressure force can be less than the second pressure force.

Referring now to FIGS. 2-4, in use, the position of the flexure element 38 is adjusted to contact an outer edge 136 of the substrate 16 thereby adjusting a position of the substrate 16. By operating the adjustment member 52 to extend toward the second position, the drive arm 54 is moved in the direction A1 toward the substrate 16. As such, the first end 72 of the preload arm 56 pivots with respect to the leaf hinge 58 and compresses the biasing member 90 to a compressed state from the original expanded state. The motion of the flexure element 38 moves the tab 88 radially toward the outer edge 136 of the substrate 16 until the tab 88 contacts the outer edge 136 of the substrate 16. The tab 88 then pushes the substrate 16 in a radial direction to radially position the substrate 16. It should be understood that each of the centering devices 12 operate in the same manner independently to contact the outer edge 136 of the substrate 16 at their respective positions on the mounting frame 14 and thereby adjust the position of the substrate 16.

It should be appreciated that the above embodiments utilizing the tab 88 on the flexure element 38 facilitates adjusting the radial position of the substrate 16 by contacting the outer edge 136 of the substrate 16. However, it may be desirable to entirely avoid contact with the substrate 16 when adjusting the position of the substrate 16 to avoid damaging the substrate 16 or contaminating the substrate 16, and ensuring that the measurements taken are accurate with the least amount of interference.

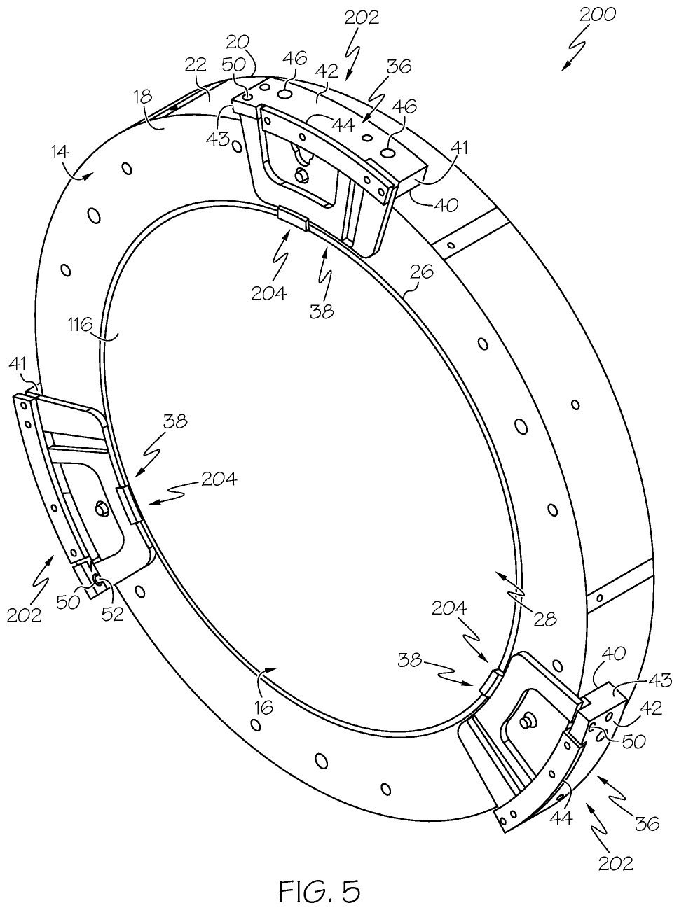

Thus, as shown in FIGS. 5-10, another embodiment of a substrate positioning device 200 is provided including a plurality of centering devices 202 that do not contact any portion of the substrate 16 when radially adjusting the position of the substrate 16. It should be appreciated that the structure and manner of operation of the substrate positioning device 200 is substantially similar to the substrate positioning device 10 discussed herein. Therefore, like parts will be provided with like reference numerals throughout the ensuing description.

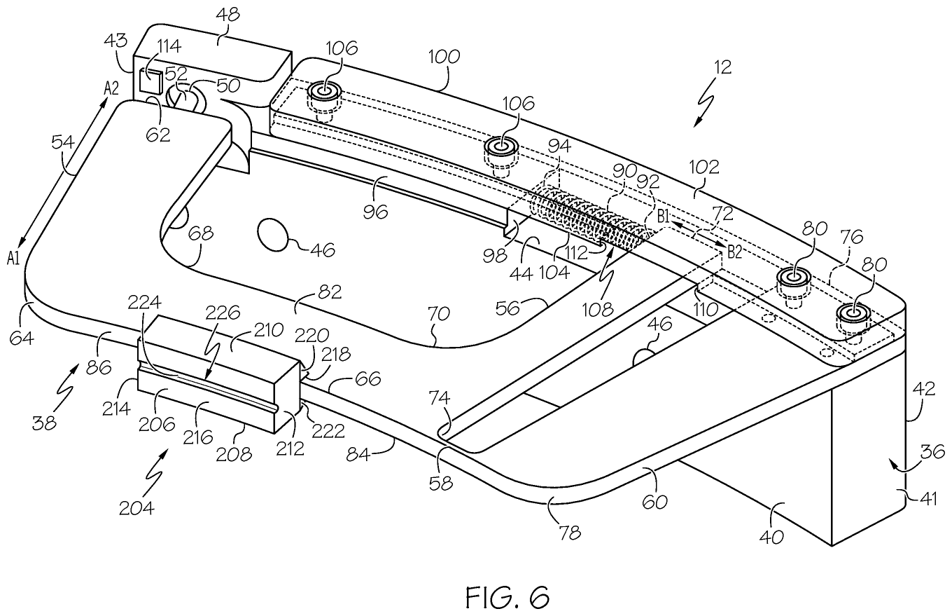

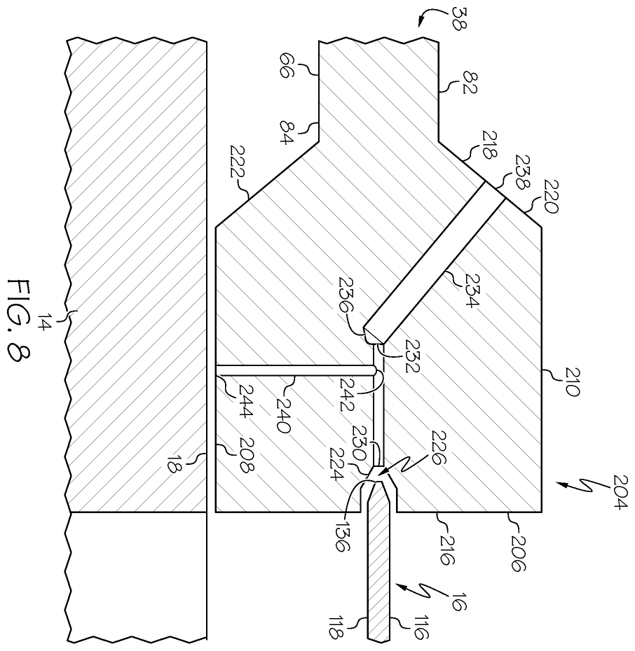

Referring now to FIG. 6, similar to the centering device 12 of the substrate positioning device 10 discussed above, the centering device 202 includes the mount 36 and the flexure element 38 coupled to the mount 36. The flexure element 38 includes the leg 66 interconnecting the second end 64 of the drive arm 54 and the second end 74 of the preload arm 56, and the fixed arm 60 is interconnected to the preload arm 56 by the leaf hinge 58. However, the centering device 202 does not include the tab 88 fixed to the radial edge 86 of the flexure element 38. Instead, the centering device 202 includes a radial air bearing 204 for radially positioning the substrate 16 (FIG. 8) without contacting the outer edge 136 of the substrate 16, as discussed in more detail below.

The radial air bearing 204 includes a body 206 having a first surface 208, a second surface 210, a first end 212, a second end 214, an interior surface 216, and an exterior surface 218. As shown, the radial air bearing 204 is provided proximate the leg 66 of the flexure element 38. In some embodiments, the exterior surface 218 of the body 206 includes a pair of teeth 220, 222 extending toward the mount 36 for securing the radial air bearing 204 to the flexure element 38. The teeth 220, 222 of the radial air bearing 204 may be fixed to the flexure element 38 by any suitable means such as, for example, mechanical fasteners, welding, adhesives, and the like. In some embodiments, the radial air bearing 204 is integrally formed with the flexure element 38 as a one piece, monolithic structure formed of the same material.

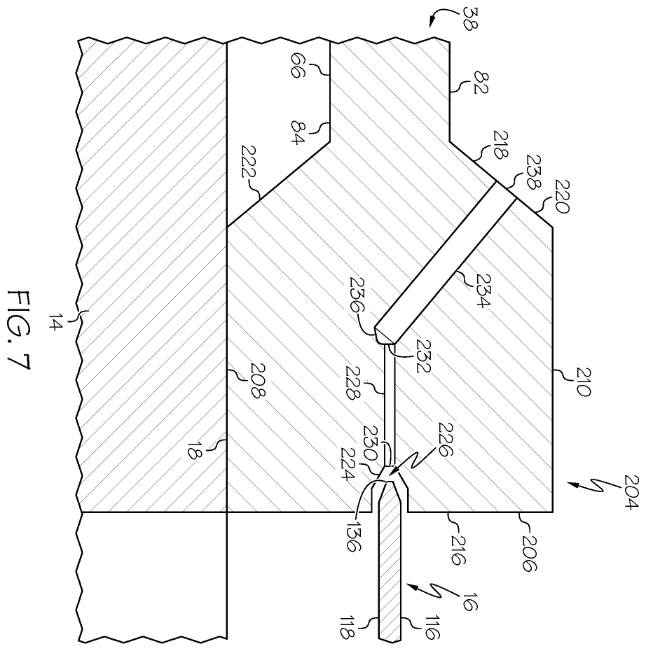

As shown in FIGS. 6 and 7, the interior surface 216 of the radial air bearing 204 includes a recess wall 224 defining a radial cavity 226 extending between the first end 212 and the second end 214 of the body 206. However, in some embodiments, the radial cavity 226 extends only partially between the first end 212 and the second end 214 of the body 206 and, thus, has a shorter length than the body 206 itself.

The radial air bearing 204 includes a first flow channel 228 having a first end 230 extending from the recess wall 224 defining the radial cavity 226 toward the flexure element 38 at a second end 232. A supply flow channel 234 is provided having a first end 236 extending from the second end 232 of the first flow channel 228 to a second end 238 terminating at the exterior surface 218 of the body 206 of the radial air bearing 204. As shown, the supply flow channel 234 extends through one of the teeth 220. However, it should be appreciated that, in some embodiments, the supply flow channel 234 extends through the leg 66 of the flexure element 38. In some embodiments, the diameter of the supply flow channel 234 is greater than the diameter of the first flow channel 228 to regulate and deliver the flow of a gaseous fluid such as, for example, air, through the supply flow channel 234 and the first flow channel 228 into the radial cavity 226.

In some embodiments, the distance between radial cavities 226 of opposing radial air bearings 204 may be less than the diameter of the substrate. Thus, as shown, the outer edge 136 of the substrate 16 is received within the radial cavity 226 of the radial air bearing 204. However, there is a space provided between the substrate 16 and the radial cavity 226 of the radial air bearing 204 to prevent physical contact with the substrate 16.

In use, a constant flow of air is delivered to the radial cavity 226 to form an air cushion between the outer edge 136 of the substrate 16 and the recess wall 224 of the radial cavity 226. The adjustment member 52 and the flexure element 38, as shown in FIG. 6, are then adjusted in the same manner as discussed above with respect to the centering device 12 to move the radial air bearing 204 in the direction A1 toward the substrate 16 and in the direction A2 away from the substrate 16 as necessary to move the substrate 16 in a radial direction with respect to the interior surface 40 of the mount 36. It should be appreciated that as the radial air bearing 204 moves in the direction A1 toward the substrate 16, the flow of air shifts radially shifts the substrate 16, thereby moving the substrate 16 without any physical contact.

As shown in FIG. 7, the first surface 208 of the body 206 of the radial air bearing 204 is in abutting relation with the first surface 18 of the mounting frame 14. As a result, the radial air bearing 204 may be in physical contact with mounting frame 14. However, as shown in FIG. 8, in another embodiment, a second flow channel 240 is provided to form an air cushion between the first surface 18 of the mounting frame 14 and the first surface 208 of the body 206 of the radial air bearing 204. The second flow channel 240 has a first end 242 and a second end 244 and extends substantially orthogonal to the first flow channel 228. Specifically, the first end 242 of the second flow channel 240 extends from the first flow channel 228 and terminates at the second end 244 at either the first surface 208 or the second surface 210 of the radial air bearing 204. As shown, the second end 244 of the second flow channel 240 terminates at the first surface 208 of the radial air bearing 204. Air flowing from the supply flow channel 234 to the first flow channel 228 enters the second flow channel 240 as well to form the air cushion between the mounting frame 14 and the radial air bearing 204. Preventing physical contact and friction between the mounting frame 14 and the radial air bearing 204 reduces the likelihood of debris entering the substrate positioning device 10 and contaminating the substrate 16.

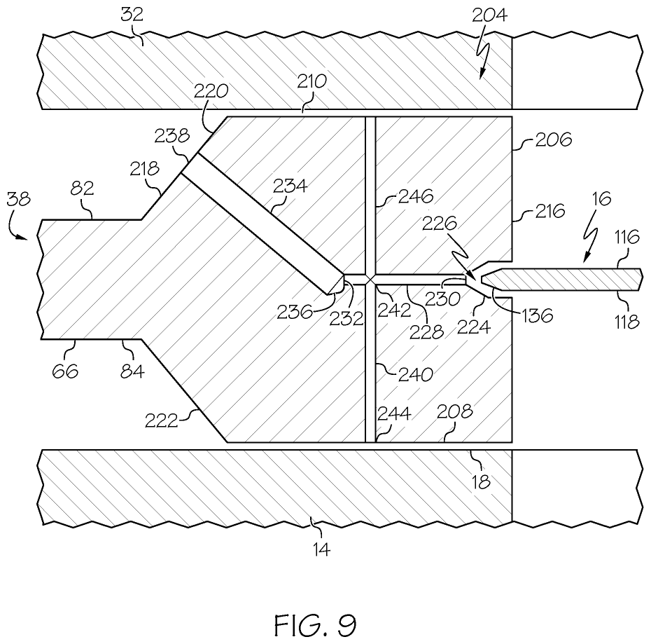

As shown in FIG. 9, the second mounting frame 32 may be provided on the opposite second surface 210 of the radial air bearing 204 when the second support 34 (FIG. 4) is also provided. FIG. 9 illustrates the second flow channel 240 and a third flow channel 246 extending substantially orthogonal to the first flow channel 228 and in opposite directions therefrom toward opposite first and second surfaces 208, 210 of the radial air bearing 204. As noted above, air flowing through the second flow channel 240 forms an air cushion between the first surface 208 of the radial air bearing 204. Similarly, air flowing through the third flow channel 246 forms an air cushion between the second surface 210 of the radial air bearing 204 and the second mounting frame 32.

It is to be understood that the first flow channel 228, the second flow channel 240, the third flow channel 246, and the supply flow channel 234 may each comprise a rigid member extending through the radial air bearing 204 or may be defined by a bore formed through the body 206 of the radial air bearing 204. In some embodiments, the radial air bearing 204 comprises a porous material such that it is a porous air bearing. When the radial air bearing 204 is a porous air bearing, air flowing through the first flow channel 228, the second flow channel 240, and the third flow channel 246 is dispersed throughout the body 206 of the radial air bearing 204 to more efficiently flow through the radial cavity 226 formed in the interior surface 216 of the radial air bearing 204.

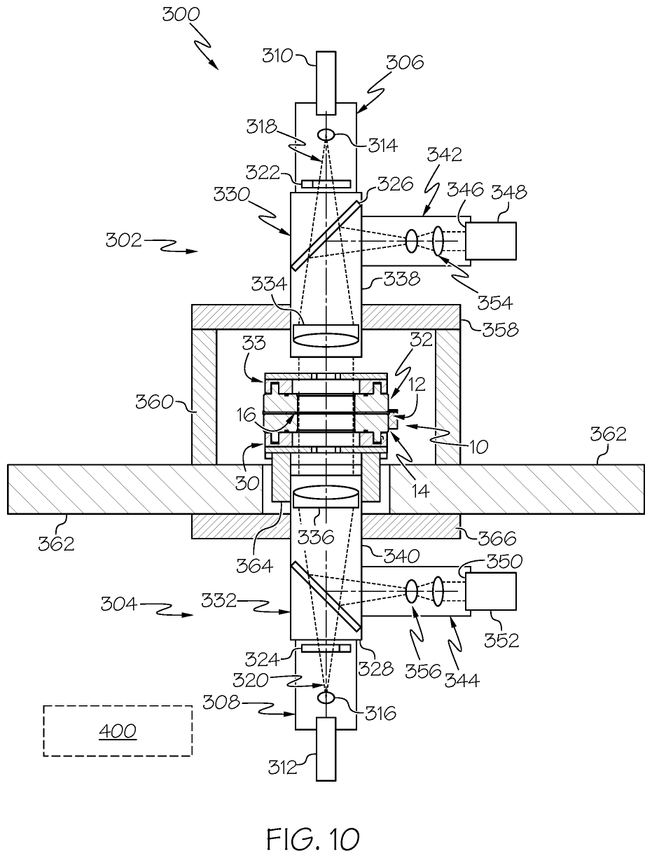

As shown in FIG. 10, the substrate positioning device 10 is provided within an interferometer 300. It should be appreciated that interferometer 300 could similarly utilize the substrate positioning device 10. The interferometer 300 in FIG. 10 is a compound interferometer which includes an upper interferometer 302 and a lower interferometer 304 for measuring opposite surfaces of the substrate 16. Although FIG. 10 depicts the interferometer 300 as a compound interferometer that is configured to measure the substrate 16 from opposite surfaces, other types of interferometers, including a single interferometer which measures the substrate 16 from one side, are contemplated. In addition, although described herein as being used to measure a substrate 16, it is contemplated that the interferometer 300 can be used to measure any opaque test part that is made of materials that are not transmissive within the range of frequencies propagated by the interferometers 302, 304, or that is sufficiently diffuse to preclude the ordered transmissions of such frequencies.

The upper and lower interferometers 302, 304 respective first and second illuminators 306, 308, which can include customary light sources 310, 312 and beam shapers 314, 316 for outputting coherent first and second measuring beams 318, 320. For example, the light sources 310, 312 can be semiconductor diode lasers, and the beam shapers 314, 316 can include beam expanders and conditioners for affecting distributions of light within the measuring beams 318, 320.

Within their respective upper and lower interferometers 302, 304, the first and second measuring beams 318, 320 propagate through first and second shutters 322, 324 to first and second beam splitters 326, 328, where the first and second measuring beams 318, 320 are directed (e.g., transmitted) into first and second measurement arms 330, 332. Opening and closing of the first and second shutters 322, 324 can be coordinated by a common processor/controller 400 for alternately blocking the propagation of one or the other of the first and second measuring beams 318, 320 to prevent light from one interferometer 302, 304 from mixing with the light from the other interferometer 302, 304. The first and second beam splitters 326, 328 can take the form of pellicle beam splitters, beam splitter cubes, or beam splitter plates based on splitting amplitude or polarization.

The measurement arms 330, 332 include dual functioning optics 334, 336 within housings 338, 340, which contribute to both illuminating and imaging the substrate 16. The illuminating function of the dual optics 334, 336 generally provides for sizing and shaping respective wavefronts of the measuring beams 318, 320 to nominally match the shapes of the opposite side surfaces of the substrate 16.

The first and second measurement arms 330, 332 also include the first support 30 and the second support 33, which may include reference optics (e.g., Fizeau wedges) having reference surface for reflecting portions of the first and second measuring beams 318, 320 as reference beams. The reference optics are selected to be transmissive within the range of frequencies propagated by the interferometers 302, 304. Remaining portions of the measuring beams 318, 320 propagate through the first support 30 and the second support 33, and certain transverse sections of the remaining portions of the measuring beams 318, 320 reflect from the opposite side surfaces of the substrate 16 as test object beams.

A first reflected test object beams and a first reference beam both propagate along a common optical pathway through the measurement arm 330 to the beam splitter 326, where at least portions of the beams are directed (e.g., reflected) into a recording arm 342 of the upper interferometer 302. Similarly, a second reflected test object beam and a second reference beam both propagate along a common optical pathway through the measurement arm 332 to the beam splitter 328, where at least portions of the beams are directed (e.g., reflected) into a recording arm 344 of the lower interferometer 304.

Within the recording arm 342, the interference patterns formed at the second support 33 are imaged onto a detector surface 346 of a camera 348. Similarly, within the recording arm 344, the interference patterns formed at the first support 30 are imaged onto a detector surface 350 of a camera 352. The detector surfaces 346, 350 can include detector arrays for measuring beam intensity throughout a field of view encompassing the opposite side surfaces of the substrate 16. The dual optics 334, 336 can contribute to the formation of the referenced images onto the detector surface 346, 350. However, the cameras 348, 352 can include or be associated with imaging optics 354, 356 for resizing or otherwise completing the imaging of the referenced images onto the detector surfaces 346, 350.

The housing 338 of the measurement arm 330 has no direct physical connection to the second support 33 independently of the mounting. Instead, the housing 338 of the measurement arm 330 is mounted via a flange 358 and a collar 360 to a base 362, which preferably has a substantial mass (e.g., as a granite slap or steel plate) to isolate the upper interferometer 302 from environmental disturbances. The substrate positioning device 10, however, is connected through a collar 364 to the housing 340 of the measurement arm 332, and the housing 340 of the measurement arm 332 is connected through a flange 366 to the base 362.

From the above, it is to be appreciated that defined herein is a substrate positioning device for radially positioning a substrate by selectively actuating at least one centering device of a plurality of centering devices. This provides a substrate positioning device that may radially position a substrate while limiting contact to opposite surfaces of the substrate.

While particular embodiments have been illustrated and described herein, it should be understood that various other changes and modifications may be made without departing from the scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A substrate positioning device comprising:
a first mounting frame; and
a plurality of centering devices coupled to the first mounting frame and spaced apart from one another, each centering device comprising a mount, a flexure element coupled to the mount and having a radial edge, and an adjustment member coupled to the mount, the adjustment member actuatable between a retracted state and an extended state for pivoting the flexure element between a first position and a second position with respect to the mount,
wherein each centering device is separately actuatable to move the flexure element of a respective centering device with respect to an edge of a substrate thereby radially positioning the substrate with respect to the first mounting frame.

2. The substrate positioning device of claim 1, further comprising a first support including at least one first gas inlet, the first mounting frame being coupled to the first support.

3. The substrate positioning device of claim 2, wherein the plurality of centering devices are positioned between the first support and a second support including at least one second gas inlet.

4. The substrate positioning device of claim 1, wherein the plurality of centering devices are equidistantly spaced apart from one another along the first mounting frame.

5. The substrate positioning device of claim 1, wherein the flexure element includes:
a drive arm;
a preload arm;
a fixed arm;
a leg interconnecting the drive arm and the preload arm; and
a leaf hinge interconnecting the preload arm and the fixed arm, wherein the drive arm, the preload arm, and the leg pivot with respect to the mount about the leaf hinge when the adjustment member moves between the retracted state and the extended state and the flexure element moves between the first position and the second position, respectively.

6. The substrate positioning device of claim 5, wherein each centering device comprises a biasing member biasing the preload arm, wherein:
the biasing member moves toward an expanded state and biases the drive arm toward the mount when the adjustment member moves toward the retracted state;
the preload arm causes the biasing member to move toward a compressed state when the adjustment member moves toward the extended state.

7. The substrate positioning device of claim 6, wherein the adjustment member extends through the mount and is coupled to the drive arm such that the flexure element is moved toward the second position and away from the mount when the adjustment member moves toward the extended state, and the flexure element is moved toward the first position and toward the mount when the adjustment member moves toward the retracted state.

8. The substrate positioning device of claim 7, wherein the adjustment member is an adjustment screw.

9. The substrate positioning device of claim 7, further comprising an adjustment sensor for measuring movement of the adjustment member between the retracted state and the extended state.

10. The substrate positioning device of claim 5, further comprising a tab provided on the radial edge of the flexure element for contacting the edge of the substrate.

11. A substrate positioning device comprising:
a first mounting frame; and
a plurality of centering devices coupled to the first mounting frame and spaced apart from one another, each centering device including a mount, a flexure element, and an adjustment member actuatable between a retracted state and an extended state for pivoting the flexure element between a first position and a second position with respect to the mount, and a radial air bearing extending from the flexure element, wherein:
the radial air bearing forms an air cushion between the radial air bearing and an edge of a substrate; and
each centering device is separately actuatable to move the flexure element of a respective centering device with respect to the edge of the substrate thereby radially positioning the substrate with respect to the first mounting frame.

12. The substrate positioning device of claim 11, further comprising a first support including at least one first gas inlet, the first mounting frame being coupled to the first support.

13. The substrate positioning device of claim 12, wherein the plurality of centering devices are equidistantly spaced apart from one another along the first mounting frame.

14. The substrate positioning device of claim 12, wherein each radial air bearing includes a radial cavity, each radial air bearing including a first flow channel delivering a flow of air to the radial cavity.

15. The substrate positioning device of claim 11, wherein the radial air bearing is a porous air bearing comprising a porous material.

16. An interferometer comprising the substrate positioning device according to claim 11.

17. A method for radially positioning a substrate, comprising:
positioning a substrate with respect to a first mounting frame;
coupling a plurality of centering devices to the first mounting frame, each centering device including a mount, a flexure element having a radial edge and positionable between a first position and a second position, and an adjustment member actuatable between a retracted state and an extended state for pivoting the flexure element with respect to the mount; and
actuating at least one of the centering devices to move the flexure element from the first position to the second position and toward an edge of the substrate to radially position the substrate with respect to the first mounting frame.

18. The method of claim 17, further comprising positioning the substrate between the first mounting frame and a second mounting frame, the flexure element of each of the plurality of centering devices positioned between the first mounting frame and the second mounting frame.

19. The method of claim 17, wherein each centering device includes an adjustment sensor, the adjustment sensors measuring a distance of a respective flexure element between the first position and the second position and corresponding this distance to a radial position of the substrate.

20. The method of claim 17, wherein each of the centering devices includes a radial air bearing for radially positioning the substrate with respect to the first mounting frame, and forming an air cushion between each of the radial air bearings and the edge of the substrate.
